(19) United States
(12) Patent Application Publication
(10) Pub. No.: US 2019/0071765 A1
(43) Pub. Date: Mar. 7, 2019

(54) METHOD FOR PRODUCING PVD ANTI-BACTERIAL FILM ON PLASTIC

(71) Applicant: Sai Chi MAK, Shenzhen City (CN)

(72) Inventor: Sai Chi MAK, Shenzhen City (CN)

(21) Appl. No.: 15/854,524

(22) Filed: Dec. 26, 2017

(30) Foreign Application Priority Data
Sep. 1, 2017 (CN) 201710779538.0

(51) Int. Cl. C23C 14/06; C23C 14/34; C23C 14/20

(52) U.S. Cl. CPC C23C 14/0682; C23C 14/205; C23C 14/3464

(57) ABSTRACT

The invention provides a method for producing a PVD anti-bacterial film on plastic. By adoption of the technical scheme, film plating can be achieved on the premise of not damaging a plastic workpiece without heating during the whole process, and a titanium target and a silicon target are used for plating a base film; plastic mainly contains a large quantity of carbon atoms and silicon atoms and has good bonding force, so that the bonding force of the film and the workpiece can be increased by plating the base film through the titanium target and the silicon target; a silver target is added for sputtering after the base film is plated, so that silver with an anti-bacterial effect is evenly distributed in a titanium silicide film, and the anti-bacterial film with the anti-bacterial effect is formed.

### BACKGROUND OF THE INVENTION

### Technical Field

The invention relates to the technical field of PVD production, in particular to a method for producing a PVD anti-bacterial film on plastic.

### 2. Description of Related Art

Plastic products have the characteristics of being easy to process, long in service life, and the like, thereby being widely used in life, a large quantity of bacteria are inevitably bred on plastic products which are frequently touched in daily life, such as household articles, child toys, handrails on vehicles, computer products, mobile phones and the like, it is even proved by people through experiments that the quantity of bacteria on mobile phones used by people every day is greater than the quantity of bacteria on toilets, and thus an effective anti-bacterial method for protecting plastic products used by people is expected by people.

PVD films have the advantages of high hardness, low friction coefficient, good abrasion resistance, chemical stability and the like, thereby being more and more popular with people. It is scientifically proved that nano-silver is an effective anti-bacterial material, PVD films containing nano-silver have already been used by people for bacterium prevention, however, heating is generally needed in the plating process of the PVD films, the plastic products have the characteristic of low ignition point, and consequentially, it is extremely difficult to directly plate the PVD films on the plastic products, and it is also difficult to plate PVD anti-bacterial films on the surfaces of the plastic products.

### BRIEF SUMMARY OF THE INVENTION

For solving the above technical problems, the invention provides a method for producing a PVD anti-bacterial film on plastic.

The method for producing the PVD anti-bacterial film on plastic comprises the following steps:

(1) pretreatment: specifically, a plastic workpiece is completely cleaned and blow-dried at a low temperature;

(2) vacuum treatment: specifically, the pretreated workpiece is placed on a hanging rack and placed into a vacuum furnace, bias voltage is loaded onto the metal hanging rack, the vacuum furnace is vacuumized until the vacuum degree reaches 0.5-1.5*10⁻³ Pa, a rotary table is started to make the workpiece rotate on the hanging rack, and the hanging rack rotates in the vacuum furnace at the same time;

(3) plating of a base film: specifically, a power source is started and regulated to 30-40V, the duty ratio is 20%-30%, argon is introduced to make the vacuum degree reach 0.3-1 Pa, and a titanium target and a silicon target are started, so that a TiSi₂ film is formed on the surface of the workpiece;

(4) plating of the anti-bacterial film: specifically, the titanium target and the silicon target are maintained, the argon flow is decreased, acetylene gas is introduced, and afterwards, a silver target is started, so that the TiSi₂/Ag anti-bacterial film is formed on the surface of the workpiece;

(5) completing of film plating: specifically, the titanium target and the silicon target are stopped first, then the silver target is stopped, afterwards, all the gases are cut off, enhanced air exhausting is conducted for 5-10 minutes for removing carbon ions left in the vacuum furnace, air is introduced into the vacuum furnace until the air pressure in the vacuum furnace reaches the barometric pressure, and film plating is completed by taking out the workpiece.

In one embodiment, the workpiece is cleaned with a plastic cleaning agent or through ultrasonic cleaning in step (1), and the blow-drying temperature is not over 60 DEG C.

In one embodiment, the bias voltage from −200V to −300V is loaded onto the metal hanging rack in step (2).

In one embodiment, the argon flow in step (3) is 100-250 sccm, the target current is 10 A, and the electroplating time is 2-10 minutes.

In one embodiment, the argon flow is decreased to 40-80 sccm in step (4), the acetylene gas flow is 150-250 sccm, and the acetylene gas is introduced for 1-5 minutes.

In one embodiment, the target current of the silver target is 0.5-1 A in step (4), and the sputtering time of the silver target is sputtered for 1-4 minutes.

In conclusion, by using the above-mentioned technical scheme for plating the PVD anti-bacterial film on plastic, film plating can be achieved on the premise of not damaging the plastic workpiece without heating during the whole process, and the titanium target and the silicon target are used for plating the base film; plastic mainly contains a large quantity of carbon atoms and silicon atoms and has good bonding force, so that the bonding force of the film and the workpiece can be increased by plating the base film through the titanium target and the silicon target; the silver target is added for sputtering after the base film is plated, so that silver with an anti-bacterial effect is evenly distributed in the titanium silicide film, and the anti-bacterial film with the anti-bacterial effect is formed; in addition, the workpiece is hung on the hanging rack in the film plating process, the workpiece revolves while rotating, so that the film is formed uniformly in the sputtering process, and damage to the workpiece caused by too high local temperature can be avoided.

### DETAILED DESCRIPTION OF THE INVENTION

For a cleaner illustration of the purpose, technical scheme and advantages of the invention, a further detailed description of the invention is given with embodiments. It should be understood that the specific embodiment described below is only used for a better understanding of the technical scheme of the invention, but is not used for limiting the invention.

A method for producing a PVD anti-bacterial film on plastic comprises the following steps:

(1) Pretreatment, specifically, a plastic workpiece is completely cleaned and blow-dried at a low temperature;

(2) vacuum treatment, specifically, the pretreated workpiece is placed on a hanging rack and then placed into a vacuum furnace, bias voltage is loaded onto the metal hanging rack, the vacuum furnace is vacuumized until the vacuum degree reaches 0.5-1.5*10⁻³ Pa, a rotary table is started to make the workpiece rotate on the hanging rack, and the hanging rack rotates in the vacuum furnace at the same time;

(3) plating of a base film: specifically, a power source is started and regulated to 30-40V, the duty ratio is 20%-30%, argon is introduced to make the vacuum degree reach 0.3-1 Pa, and a titanium target and a silicon target are started, so that a TiSi₂ film is formed on the surface of the workpiece;

(4) plating of the anti-bacterial film: specifically, the titanium target and the silicon target are kept, the argon flow is decreased, acetylene gas is introduced, and afterwards, a silver target is started, so that the TiSi₂/Ag anti-bacterial film is formed on the surface of the workpiece;

(5) completing of film plating: specifically, the titanium target and the silicon target are stopped first, then the silver target is stopped, afterwards, all gases are cut off, enhanced air exhausting is conducted for 5-10 minutes for removing carbon ions left in the vacuum furnace, air is introduced into the vacuum furnace until the air pressure in the vacuum furnace reaches the barometric pressure, and film plating is completed by taking out the workpiece. During the whole film plating process, heating is not conducted in the vacuum furnace, a water cooling system in the vacuum furnace operates normally so that the temperature can be controlled below 60 DEG C. during the whole process, and film plating is completed under the condition that the plastic workpiece is not damaged. In addition, the workpiece is arranged on the hanging rack to rotate, the hanging rack rotates in the vacuum furnace so that the workpiece can rotate and revolve at the same time in the film plating process, the film can be uniform in the film plating process of the workpiece, and the situation that the workpiece is damaged due to the fact that sputtering temperature rise of targets is excessive in the local film plating process can be avoided. Residual carbon ions in the acetylene are removed through air suction, so that the situation where the carbon ions adhere to the PVD film, and consequentially the color of the PVD film is affected, is avoided.

In one embodiment, the workpiece is cleaned with a plastic cleaning agent or through ultrasonic cleaning in step (1), and the blow-drying temperature is not over 60 DEG C. The workpiece can be cleaned in various ways, so that the surface of the workpiece is kept clean and dry before film plating, the adhesive force of the targets on the surface of the workpiece can be increased easily, the bonding force of the film is improved, and the PVD film plating quality is improved accordingly.

In one embodiment, the bias voltage from −200V to −300V is loaded onto the metal hanging rack in step (2).

In one embodiment, the argon flow in step (3) is 100-250 sccm, the target current is 10 A, and the electroplating time is 2-10 minutes. The thickness of the base film can be controlled according to the electroplating time, a transparent yellow film can be generated if the electroplating time is short, the film can be thickened and turned into a coffee color and the transparency can be reduced along with time increments, and the film plating time is controlled according to specific film plating requirements of products.

In one embodiment, the argon flow is decreased to 40-80 sccm in step (4), the acetylene gas flow is 150-250 sccm, and the acetylene gas is introduced for 1-5 minutes.

In one embodiment, the target current of the silver target is 0.5-1 A in step (4), and the sputtering time of the silver target is 1-4 minutes.

### First Embodiment

A method for producing a PVD anti-bacterial film on plastic, characterized by comprising the following steps:

(1) pretreatment: specifically, a plastic workpiece is completely cleaned and blow-dried at the temperature of 50 DEG C., and the workpiece is cleaned with a plastic cleaning agent;

(2) vacuum treatment: specifically, the pretreated workpiece is placed on a hanging rack and placed into a vacuum furnace, the bias voltage of −200V is loaded onto the metal hanging rack, the vacuum furnace is vacuumized until the vacuum degree reaches 0.5*10⁻³ Pa, a rotary table is started to make the workpiece rotate on the hanging rack, and the hanging rack rotates in the vacuum furnace at the same time;

(3) plating of a basic film: specifically, a power source is started and regulated to 30V, the duty ratio is 20%, argon at the flow of 100 sccm is introduced to make the vacuum degree reach 0.3 Pa, a titanium target with the target current of 10 A and a silicon target with the target current of 10 A are started, and electroplating is conducted for 2 minutes, so that a TiSi₂ film is formed on the surface of the workpiece;

(4) plating of the anti-bacterial film: specifically, the titanium target and the silicon target are kept, the argon flow is decreased to 40 sccm, acetylene gas at the flow of 150 sccm is introduced for one minute, afterwards, a silver target is started, so that the TiSi₂/Ag anti-bacterial film is formed on the surface of the workpiece, the target current of the silver target is 0.5 A, and the sputtering time of the silver target is one minute;

(5) completing of film plating: specifically, the titanium target and the silicon target are stopped first, then the silver target is stopped, afterwards, all the gases are cut off, enhanced air exhausting is conducted for 5 minutes for removing carbon ions left in the vacuum furnace, air is introduced into the vacuum furnace until the air pressure in the vacuum furnace reaches the barometric pressure, and film plating is completed by taking out the workpiece.

### Second Embodiment

A method for producing a PVD anti-bacterial film on plastic, characterized by comprising the following steps:

(1) pretreatment: specifically, a plastic workpiece is completely cleaned and blow-dried at the temperature of 52 DEG C., and the workpiece is cleaned with a plastic cleaning agent;

(2) vacuum treatment: specifically, the pretreated workpiece is placed on a hanging rack and then placed into a vacuum furnace, the bias voltage of −250V is loaded onto the metal hanging rack, the vacuum furnace is vacuumized until the vacuum degree reaches 1.3*10⁻³ Pa, a rotary table is started to make the workpiece rotate on the hanging rack, and the hanging rack rotates in the vacuum furnace at the same time;

(3) plating of a basic film: specifically, a power source is started and regulated to 32V, the duty ratio is 25%, argon at the flow of 170 sccm is introduced to make the vacuum degree reach 0.7 Pa, a titanium target with the target current of 10 A and a silicon target with the target current of 10 A are started, and the electroplating time is 4 minutes, so that a TiSi₂ film is formed on the surface of the workpiece;

(4) plating of the anti-bacterial film: specifically, the titanium target and the silicon target are kept, the argon flow is decreased to 50 sccm, acetylene gas at the flow of 200 sccm is introduced for two minutes, afterwards, a silver target is started, so that the TiSi₂/Ag anti-bacterial film is formed on the surface of the workpiece, the target current of the sliver target is 0.6 A, and the sputtering time of the silver target is 2 minutes;

(5) completing of film plating: specifically, the titanium target and the silicon target are stopped first, then the silver target is stopped, afterwards, all the gases are cut off, enhanced air exhausting is conducted for 6 minutes for removing carbon ions left in the vacuum furnace, air is introduced into the vacuum furnace until the air pressure in the vacuum furnace reaches the barometric pressure, and film plating is completed by taking out the workpiece.

### Third Embodiment

A method for producing a PVD anti-bacterial film on plastic, characterized by comprising the following steps:

(1) pretreatment: specifically, a plastic workpiece is completely cleaned and blow-dried at the temperature of 54 DEG C., and the workpiece is cleaned ultrasonically;

(2) vacuum treatment: specifically, the pretreated workpiece is placed on a hanging rack and then placed into a vacuum furnace, the bias voltage of −220V is loaded onto the metal hanging rack, the vacuum furnace is vacuumized until the vacuum degree reaches 1.0*10⁻³ Pa, a rotary table is started to make the workpiece rotate on the hanging rack, and the hanging rack rotates in the vacuum furnace at the same time;

(3) plating of a basic film: specifically, a power source is started and regulated to 34V, the duty ratio is 27%, argon at the flow of 200 sccm is introduced to make the vacuum degree reach 0.5 Pa, a titanium target with the target current of 10 A and a silicon target with the target current of 10 A are started, and electroplating is conducted for 6 minutes, so that a TiSi₂ film is formed on the surface of the workpiece;

(4) plating of the anti-bacterial film: specifically, the titanium target and the silicon target are kept, the argon flow is decreased to 60 sccm, acetylene gas at the flow of 180 sccm is introduced for three minutes, afterwards, a silver target is started, so that the TiSi₂/Ag anti-bacterial film is formed on the surface of the workpiece, the target current of the silver target is 0.7 A, and the sputtering time of the silver target is 3 minutes;

(5) completing of film plating: specifically, the titanium target and the silicon target are stopped first, then the silver target is stopped, afterwards, all the gases are cut off, enhanced air exhausting is conducted for 7 minutes for removing carbon ions left in the vacuum furnace, air is introduced into the vacuum furnace until the air pressure in the vacuum furnace reaches the barometric pressure, and film plating is completed by taking out the workpiece.

### Fourth Embodiment

A method for producing a PVD anti-bacterial film on plastic, characterized by comprising the following steps:

(1) pretreatment: specifically, a plastic workpiece is completely cleaned and blow-dried at the temperature of 56 DEG C., and the workpiece is cleaned ultrasonically;

(2) vacuum treatment: specifically, the pretreated workpiece is placed on a hanging rack and then placed into a vacuum furnace, the bias voltage of −280V is loaded onto the metal hanging rack, the vacuum furnace is vacuumized until the vacuum degree reaches 0.8*10⁻³ Pa, a rotary table is started to make the workpiece rotate on the hanging rack, and the hanging rack rotates in the vacuum furnace at the same time;

(3) plating of a basic film: specifically, a power source is started and regulated to 37V, the duty ratio is 23%, argon at the flow of 230 sccm is introduced to make the vacuum degree reach 0.6 Pa, a titanium target with the target current of 10 A and a silicon target with the target current of 10 A are started, and electroplating is conducted for 8 minutes, so that a TiSi₂ film is formed on the surface of the workpiece;

(4) plating of the anti-bacterial film: specifically, the titanium target and the silicon target are kept, the argon flow is decreased to 70 sccm, acetylene gas at the flow of 230 sccm is introduced for 4 minutes, afterwards, a silver target is started, so that the TiSi₂/Ag anti-bacterial film is formed on the surface of the workpiece, the target current of the silver target is 0.8 A, and the sputtering time of the silver target is 4 minutes;

(5) completing of film plating: specifically, the titanium target and the silicon target are stopped first, then the silver target is stopped, afterwards, all the gases are cut off, enhanced air exhausting is conducted for 8 minutes for removing carbon ions left in the vacuum furnace, air is introduced into the vacuum furnace until the air pressure in the vacuum furnace reaches the barometric pressure, and film plating is completed by taking out the workpiece.

### Fifth Embodiment

A method for producing a PVD anti-bacterial film on plastic, characterized by comprising the following steps:

(1) pretreatment: specifically, a plastic workpiece is completely cleaned and blow-dried at the temperature of 58 DEG C., and the workpiece is cleaned ultrasonically;

(2) vacuum treatment: specifically, the pretreated workpiece is placed on a hanging rack and then placed into a vacuum furnace, the bias voltage of −300V is loaded onto the metal hanging rack, the vacuum furnace is vacuumized until the vacuum degree reaches 1.5*10⁻³ Pa, a rotary table is started to make the workpiece rotate on the hanging rack, and the hanging rack rotates in the vacuum furnace at the same time;

(3) plating of a basic film: specifically, a power source is started and regulated to 40V, the duty ratio is 30%, argon at the flow of 250 sccm is introduced to make the vacuum degree reach 1 Pa, a titanium target with the target current of 10 A and a silicon target with the target current of 10 A are started, and electroplating is conducted for 2-10 minutes, so that a TiSi₂ film is formed on the surface of the workpiece;

(4) plating of the anti-bacterial film: specifically, the titanium target and the silicon target are kept, the argon flow is decreased to 80 sccm, acetylene gas at the flow of 250 sccm is introduced for 5 minutes, afterwards, a silver target is started, so that the TiSi₂/Ag anti-bacterial film is formed on the surface of the workpiece, the target current of the silver target is 1 A, and the sputtering time of the silver target is 4 minutes;

(5) completing of film plating: specifically, the titanium target and the silicon target are stopped first, then the silver target is stopped, afterwards, all gases are cut off, enhanced air exhausting is conducted for 10 minutes for removing carbon ions left in the vacuum furnace, air is introduced into the vacuum furnace until the air pressure in the vacuum furnace reaches the barometric pressure, and film plating is completed by taking out the workpiece.

### Six Embodiment

The film bonding force of a plastic workpiece plated with the PVD anti-bacterium film obtained in the embodiments 1-5 is measured based on experimental data, the result is shown as the following table:

| | Embodiment | | | | |
|---|---|---|---|---|---|
| | 1 | 2 | 3 | 4 | 5 |
| Bonding | 62 | 63.8 | 65 | 64 | 68 |
| Force (N) | | | | | |

It can be known from the experiment result that the film bonding force of the PVD anti-bacterial film, obtained through the technical scheme, on the plastic surface is over 60N, it indicates that the film bonding force is excellent and can meet requirements of ordinary plastic products.

### Seventh Embodiment

The plastic workpieces in embodiments 1-5 are all door handles made of the same material, an ordinary common plastic door handle made of the same material as the door handles in the embodiment 1-5 is used as a comparison set, the quantities of bacteria falling onto six samples in the same service environment are measured six hours later and twelve hours later respectively, the result is shown as the following table:

| Experimental | First | Second | Third | Fourth | Fifth | Comparison |
|---|---|---|---|---|---|---|
| Sample | embodiment | embodiment | embodiment | embodiment | embodiment | set |
| 6 h | 25 | 23 | 25 | 21 | 19 | 38 |
| (number/cm²) | | | | | | |
| 12 h | 30 | 26 | 29 | 27 | 22 | 49 |
| (number/cm²) | | | | | | |

It can be known from the experiment result that compared with the ordinary handle, the plastic door handle provided with the PVD anti-bacterial film in the technical scheme has remarkable anti-bacterial effect and also has extremely high actual use value.

The above embodiments are only preferred embodiments of the invention, It should be pointed out that those skilled in the field can make various improvements and transformations without deviating from the principle of the invention, and all the improvements and the transformations are also within the protection scope of the invention.

What is claimed is:

1. A method for producing a PVD anti-bacterial film on plastic, characterized by comprising the following steps:
(1) pretreatment: specifically, a plastic workpiece is completely cleaned and blow-dried at a low temperature;
(2) vacuum treatment: specifically, the pretreated workpiece is placed on a hanging rack and then placed into a vacuum furnace, bias voltage is loaded onto the metal hanging rack, the vacuum furnace is vacuumized until the vacuum degree reaches 0.5-1.5*10⁻³ Pa, a rotary table is started to make the workpiece rotate on the hanging rack, and the hanging rack rotates in the vacuum furnace at the same time;
(3) plating of a base film: specifically, a power source is started and regulated to 30-40V, the duty ratio is 20%-30%, argon is introduced to make the vacuum degree reach 0.3-1 Pa, and a titanium target and a silicon target are started, so that a TiSi₂ film is formed on the surface of the workpiece;
(4) plating of the anti-bacterial film: specifically, the titanium target and the silicon target are kept, the argon flow is decreased, acetylene gas is introduced, and afterwards, a silver target is started, so that the TiSi₂/Ag anti-bacterial film is formed on the surface of the workpiece;
(5) completing of the film plating: specifically, the titanium target and the silicon target are stopped first, then the silver target is stopped; afterwards, all the gases are cut off, enhanced air exhausting is conducted for 5-10 minutes for removing the carbon ions left in the vacuum furnace, air is introduced into the vacuum furnace until the air pressure in the vacuum furnace reaches the barometric pressure, and film plating is completed by taking out the workpiece.

2. The method for producing the PVD anti-bacterial film on plastic according to claim 1, characterized in that the workpiece is cleaned with a plastic cleaning agent or through ultrasonic cleaning in step (1), and the blow-drying temperature is not over 60 DEG C.

3. The method for producing the PVD anti-bacterial film on plastic according to claim 1, characterized in that the bias voltage from −200V to −300V is loaded onto the metal hanging rack in step (2).

4. The method for producing the PVD anti-bacterial film on plastic according to claim 1, characterized in that the argon flow in step (3) is 100-250 sccm, the target current is 10 A, and the electroplating time is 2-10 minutes.

5. The method for producing the PVD anti-bacterial film on plastic according to claim 1, characterized in that the argon flow is decreased to 40-80 sccm in step (4), the acetylene gas flow is 150-250 sccm, and the acetylene gas is introduced for 1-5 minutes.

6. The method for producing the PVD anti-bacterial film on plastic according to claim 1, characterized in that the target current of the silver target is 0.5-1 A in step (4), and the sputtering time of the silver target is sputtered for 1-4 minutes.
